(19) United States
(12) Patent Application Publication
(10) Pub. No.: US 2026/0099437 A1
(43) Pub. Date: Apr. 9, 2026

(54) INFORMATION CODE PROCESSOR, MEMORY, AND OPERATING METHOD THEREOF

(71) Applicant: SK hynix Inc., Gyeonggi-do (KR)

(72) Inventor: Chang Hyun KIM, Gyeonggi-do (KR)

(21) Appl. No.: 18/969,261

(22) Filed: Dec. 5, 2024

(30) Foreign Application Priority Data
Oct. 8, 2024 (KR) 10-2024-0136568

(51) Int. Cl. G06F 12/02

(52) U.S. Cl. CPC G06F 12/0223

(57) ABSTRACT

An information code processor may include a first sampling circuit configured to sample an information code at a first time point to generate a first sampling code, a second sampling circuit configured to sample the information code at a second time point subsequent to the first time point to generate a second sampling code, and a processing circuit configured to generate a processing code, using the first sampling code, the second sampling code and a pre-processing code generated previously.

### CROSS-REFERENCE TO RELATED APPLICATION(S)

This application claims priority under 35 U.S.C. § 119 to Korean Patent Application No. 10-2024-0136568, filed on Oct. 8, 2024, the disclosure of which is incorporated herein by reference in its entirety.

### BACKGROUND

### 1. Technical Field

Various embodiments of the present disclosure relate to an integrated circuit, and more particularly, to a memory and an information code processor for processing an information code including internal information of an integrated circuit such as a memory.

### 2. Related Art

Because various integrated circuits include a large number of transistors, their electrical characteristics may vary depending on an operating temperature. For example, in a memory such as a DRAM, data retention time varies depending on a temperature, and thus temperature information is exchanged between the memory and a memory controller to adjust a refresh period depending on the temperature.

In a case where temperature information generated by a temperature sensing circuit included in an integrated circuit is outputted outside the integrated circuit, a glitch may occur when timing at which the temperature information is updated overlaps with timing at which the temperature information is outputted, and the temperature information may be changed and outputted due to various other factors. Therefore, technology for stably processing and outputting the temperature information generated in the integrated circuit is required.

### SUMMARY

In accordance with an embodiment of the present disclosure, an information code processor may include a first sampling circuit configured to sample an information code at first time point to generate a first sampling code; a second sampling circuit configured to sample the information code at second time point subsequent to the first time point to generate a second sampling code; and a processing circuit configured to generate a processing code, using the first sampling code, the second sampling code and a pre-processing code generated previously.

In accordance with an embodiment of the present disclosure, a memory may include a temperature sensing circuit configured to generate an information code indicating a temperature; a command decoder configured to decode a command and an address to generate a temperature read signal; a first sampling circuit configured to sample the information code at first time point in response to the temperature read signal to generate a first sampling code; a second sampling circuit configured to sample the information code at second time point subsequent to the first time point in response to the temperature read signal to generate a second sampling code; a processing circuit configured to generate a processing code, using the first sampling code, the second sampling code and a pre-processing code generated previously; and a transmitting circuit configured to transmit the processing code.

In accordance with an embodiment of the present disclosure, a method of operating a memory may include generating an information code indicating a temperature; decoding a command and an address to generate a temperature read signal; sampling the information code at first time point in response to the temperature read signal to generate a first sampling code; sampling the information code at second time point subsequent to the first time point in response to the temperature read signal to generate a second sampling code; and generating a processing code based on the first sampling code, the second sampling code and a pre-processing code generated previously, to externally transmit the processing code.

### BRIEF DESCRIPTION OF THE DRAWINGS

FIG. 1 is a block diagram illustrating a memory in accordance with an embodiment of the present disclosure.

FIG. 2 is a block diagram illustrating an embodiment of an information code processor illustrated in FIG. 1.

FIG. 3 is a block diagram illustrating an embodiment of a processing circuit illustrated in FIG. 2.

FIG. 4 is a block diagram illustrating another embodiment of the information code processor illustrated in FIG. 1.

FIG. 5 is a block diagram illustrating an embodiment of a code correction circuit illustrated in FIG. 4.

### DETAILED DESCRIPTION

Various embodiments of the present disclosure are directed to technology of stably processing an information code generated by an integrated circuit.

According to embodiments of the present disclosure, it is possible to stably process an information code generated by an integrated circuit and output the processed information code to outside the integrated circuit.

Hereinafter, various embodiments according to the technical spirit of the present disclosure are described below with reference to the accompanying drawings.

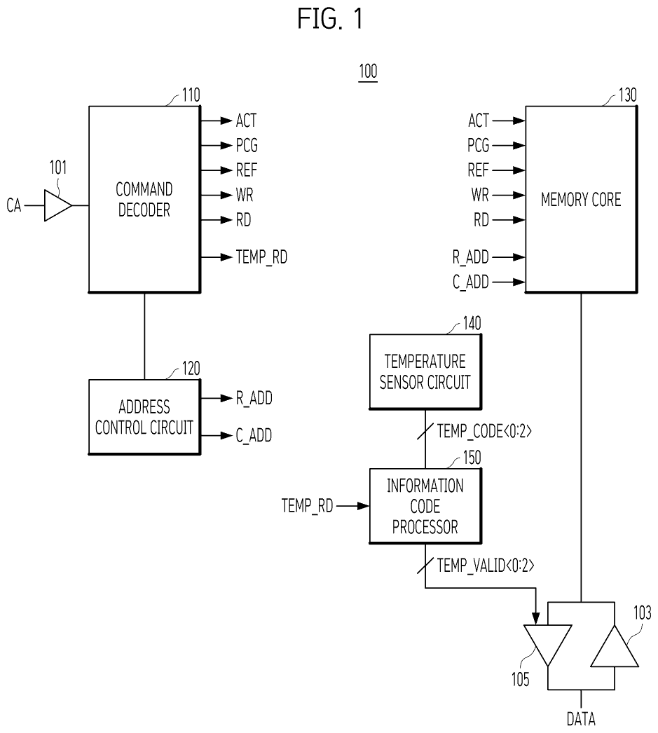

FIG. 1 is a block diagram illustrating a memory 100 in accordance with an embodiment of the present disclosure.

Referring to FIG. 1, the memory 100 may include a command address receiving circuit 101, a data receiving circuit 103, a data transmitting circuit 105, a command decoder 110, an address control circuit 120, a memory core 130, a temperature sensing circuit 140, and an information code processor 150.

The command address receiving circuit 101 may receive a command and an address CA. Depending on the specifications of the memory 100, the command and address CA may be inputted through the same input terminals or separate input terminals. Herein, it is illustrated that the command and address CA are inputted through the same input terminals. The command and address CA may have multi-bits.

The data receiving circuit 103 may receive data DATA, and the data transmitting circuit 105 may transmit data DATA. During a write operation, the data receiving circuit 103 may receive the data DATA to be written to the memory core 130, and during a read operation, the data transmitting circuit 105 may transmit the data DATA read from the memory core 130.

The command decoder 110 may decode the command and address CA and find out a type of operation that a memory controller instructs the memory 100 to perform. An active signal ACT may be activated when an active operation is instructed, a pre-charge signal PCG may be activated when a pre-charge operation is instructed, and a refresh signal REF may be activated when a refresh operation is instructed. A write signal WR may be activated when the write operation is instructed, and a read signal RD may be activated when the read operation is instructed. In addition, a temperature read signal TEMP_RD may be activated when a request for temperature information of the memory 100 is made from the memory controller.

The address control circuit 120 may sort the address received from the command decoder 110 into a row address R_ADD and a column address C_ADD and transmit the address to the memory core 130. The address control circuit 120 may sort the address into the row address R_ADD when the active operation is instructed as a result of the decoding of the command decoder 110 and sort the address into the column address C_ADD when the read and write operations are instructed as the result of the decoding of the command decoder 110.

The memory core 130 may perform the operations instructed by the signals ACT, PCG, RD, WR and REF. The memory core 130 may include components for the active, pre-charge, read, write and refresh operations, such as a cell array including memory cells arranged in a plurality of rows and a plurality of columns, a row decoder for activating/deactivating a row of the cell array, a column decoder for inputting/outputting data from the cell array, and an input/output circuit.

The temperature sensing circuit 140 may sense an internal temperature of the memory 100 to generate an information code TEMP_CODE<0:2>.

The information code processor 150 may process the information code TEMP_CODE<0:2> in response to a temperature read signal TEMP_RD to generate a processing code TEMP_VALID<0:2>. The temperature sensing circuit 140 may operate in synchronization with a periodic wave generated by an oscillator (not illustrated) included in the memory 100, and the temperature read signal TEMP_RD may be activated in synchronization with a clock (not illustrated) applied from outside the memory 100. When the temperature read signal TEMP_RD is activated at the time when the temperature sensing circuit 140 updates or changes the information code TEMP_CODE<0:2>, it may be impossible for a value of the information code TEMP_CODE<0:2> to be transmitted correctly. In addition, a glitch may occur in the value of the information code TEMP_CODE<0:2> for various other reasons, and the information code processor 150 may process the information code TEMP_CODE<0:2> so that the value of the information code TEMP_CODE<0:2> may be outputted to outside the memory 100 stably without an error.

The processing code TEMP_VALID<0:2> obtained by the processing of the information code processor 150 may be transmitted to the memory controller by the data transmitting circuit 105. Herein, it is illustrated that the processing code TEMP_VALID<0:2> is transmitted to the memory controller by the data transmitting circuit 105, but depending on design, a separate transmitting circuit may be provided to transmit the processing code TEMP_VALID<0:2> to the memory controller.

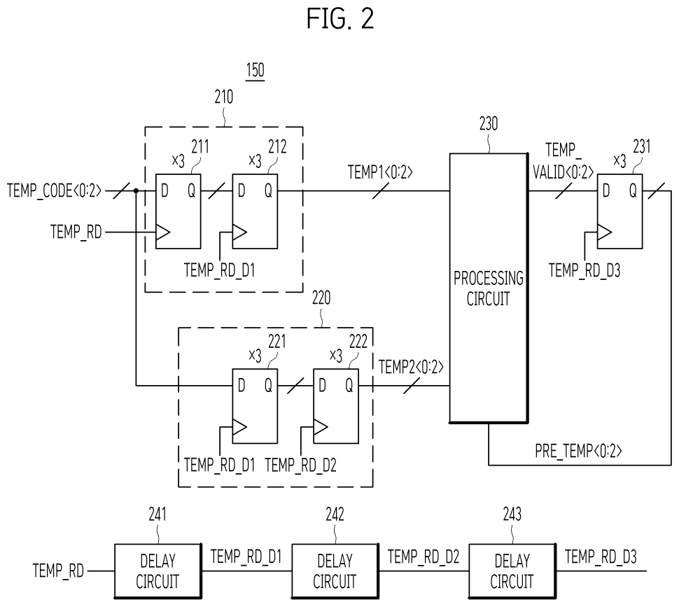

FIG. 2 is a block diagram illustrating an embodiment of the information code processor 150 illustrated in FIG. 1.

Referring to FIG. 2, the information code processor 150 may include a first sampling circuit 210, a second sampling circuit 220, a processing circuit 230, and delay circuits 241 to 243.

The first sampling circuit 210 may sample the information code TEMP_CODE<0:2> when the temperature read signal TEMP_RD is activated. The first sampling circuit 210 may include D flip-flops 211 and 212. The D flip-flops 211 receive and store the information code TEMP_CODE<0:2> at the activation time of the temperature read signal TEMP_RD. When the activation time of the temperature read signal TEMP_RD coincides with time at which the information code TEMP_CODE<0:2> changes or is updated, internal nodes and output values of the D flip-flops 211 may become unstable and fall into a meta-stable state. For this reason, the D flip-flops 212 are provided. The D flip-flops 212 sample and store the output of the D flip-flops 211 again in response to activation of a temperature read signal TEMP_RD_D1 obtained by delaying the temperature read signal TEMP_RD by the delay circuit 241, to output the result as a first sampling code TEMP1<0:2>.

The second sampling circuit 220 samples the information code TEMP_CODE<0:2> at later time than sampling time of the first sampling circuit 210, that is, when the temperature read signal TEMP_RD_D1 is activated. D flip-flops 221 receive and store the information code TEMP_CODE<0:2> at the activation time of the temperature read signal TEMP_RD_D1. D flip-flops 222 sample and store the output of the D flip-flops 221 again when a temperature read signal TEMP_RD_D2 obtained by further delaying the temperature read signal TEMP_RD_D1 by the delay circuit 242 is activated, and output the result as a second sampling code TEMP2<0:2>.

The processing circuit 230 may generate a processing code TEMP_VALID<0:2> using the first sampling code TEMP1<0:2>, the second sampling code TEMP2<0:2> and a pre-processing code PRE_TEMP<0:2> generated previously. The pre-processing code PRE_TEMP<0:2> may be a processing code generated previously by the processing circuit 230. D flip-flops 231 may sample the processing code TEMP_VALID<0:2>, which is the output of the processing circuit 230, when a temperature read signal TEMP_RD_D3 obtained by delaying the temperature read signal TEMP_RD_D2 by the delay circuit 243 is activated, to generate the pre-processing code PRE_TEMP<0:2>.

The processing circuit 230 may generate the processing code TEMP_VALID<0:2> having a stable value through the following processing.

(1) In a case where a value of the first sampling code TEMP1<0:2> is equal to a value of the second sampling code TEMP2<0:2>.

When the value of the first sampling code TEMP1<0:2> is equal to the value of the second sampling code TEMP2<0:2>, where the two sampling codes are sampled at a slight time difference, it may be determined that there is no error in the values of the sampled codes. Therefore, in this case, the processing code TEMP_VALID<0:2> may be generated to have the same value as the first sampling code TEMP1<0:2>.

(2) In a case where the value of the first sampling code TEMP1<0:2> is different from the value of the second sampling code TEMP2<0:2>.

When the value of the first sampling code TEMP1<0:2> is different from the value of the second sampling code TEMP2<0:2>, where the two sampling codes are sampled at a slight time difference, neither the first sampling code TEMP1<0:2> nor the second sampling code TEMP2<0:2> is reliable. Therefore, the processing circuit 230 may generate the processing code TEMP_VALID<0:2> as described in the following (2-1), (2-2), and (2-3).

(2-1) In a case where the values of the first sampling code TEMP1<0:2> and second sampling code TEMP2<0:2> are less than a value of the pre-processing code PRE_TEMP<0:2>.

In this case, it may be determined that the value of the information code TEMP_CODE<0:2> becomes smaller compared to the pre-processing code PRE_TEMP<0:2>, which is the previous value. Accordingly, the processing circuit 230 may generate the processing code TEMP_VALID<0:2> having a value obtained by subtracting a predetermined first value (e.g., “1”) from the value of the pre-processing code PRE_TEMP<0:2>.

(2-2) In a case where the values of the first sampling code TEMP1<0:2> and second sampling code TEMP2<0:2> are greater than the value of the pre-processing code PRE_TEMP<0:2>.

In this case, it may be determined that the value of the information code TEMP_CODE<0:2> becomes larger compared to the pre-processing code PRE_TEMP<0:2>, which is the previous value. Accordingly, the processing circuit 230 may generate the processing code TEMP_VALID<0:2> having a value obtained by adding a predetermined second value (e.g., “1”) to the value of the pre-processing code PRE_TEMP<0:2>.

(2-3) In a case where the value of the first sampling code TEMP1<0:2> is different from the value of the second sampling code TEMP2<0:2> and that is not the cases (2-1) and (2-2).

In this case, both of the values of the first sampling code TEMP1<0:2> and second sampling code TEMP2<0:2> are not reliable. Therefore, the processing circuit 230 may generate the processing code TEMP_VALID<0:2> having the same value as the value of the pre-processing code PRE_TEMP<0:2>.

Because the quantity of bits of the information code TEMP_CODE<0:2> illustrated is 3 bits, the quantity of each of the D flip-flops 211, 212, 221, 222 and 231 may be 3, and when the quantity of bits of the information code changes, the quantity of each of the D flip-flops may also change.

In addition, although the final output of the information code processor 150 is illustrated as the processing code TEMP_VALIDE<0:2>, the final output of the information code processor 150 may also be the pre-processing code PRE_TEMP<0:2>. Because the pre-processing code PRE_TEMP<0:2> is a code obtained by sampling the processing code TEMP_VALIDE<0:2> by the D flip-flops 231, the pre-processing code PRE_TEMP<0:2> may be generated with the same value as soon as the processing code TEMP_VALIDE<0:2> is updated.

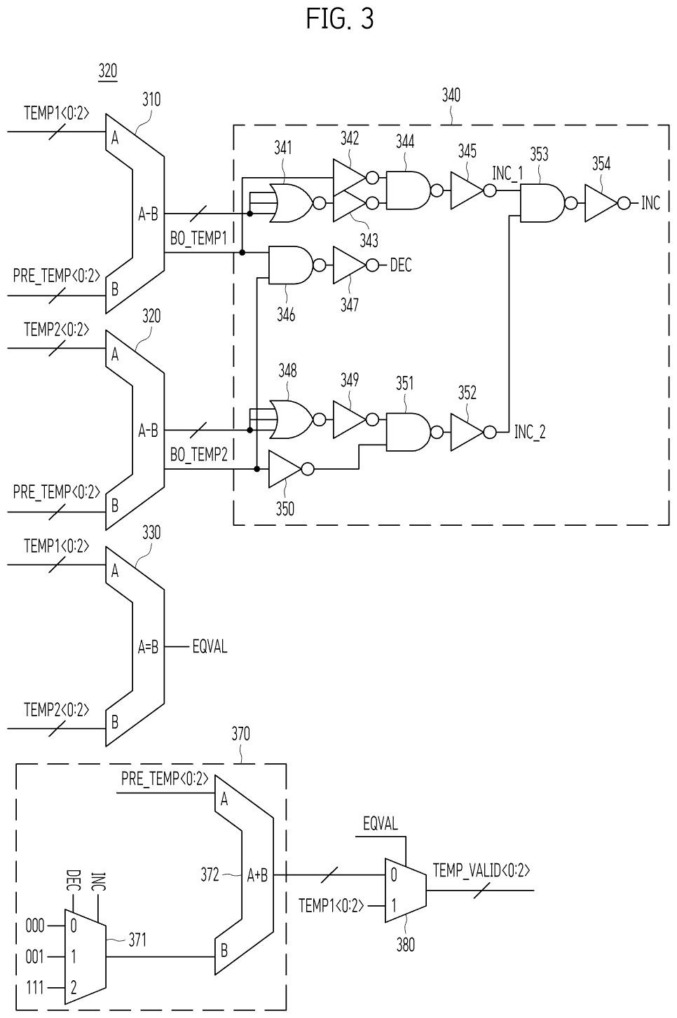

FIG. 3 is a block diagram illustrating an embodiment of the processing circuit 230 illustrated in FIG. 2.

Referring to FIG. 3, the processing circuit 230 may include a first subtraction circuit 310, a second subtraction circuit 320, a comparison circuit 330, a logic operation unit 340, an operation circuit 370, and a selection circuit 380.

The first subtraction circuit 310 may subtract the value of the pre-processing code PRE_TEMP<0:2> from the value of the first sampling code TEMP1<0:2> to generate a first subtraction result DELT_TEMP1<0:2> and a first borrow signal BO_TEMP1. When the value of the first sampling code TEMP1<0:2> is greater than the value of the pre-processing code PRE_TEMP<0:2>, the first subtraction result DELT_TEMP1<0:2> has a value, not “000”, and the first borrow signal BO_TEMP1 is deactivated. In addition, when the value of the first sampling code TEMP1<0:2> is greater than the value of the pre-processing code PRE_TEMP<0:2>, the first borrow signal BO_TEMP1 is activated to “1”.

The second subtraction circuit 320 may subtract the value of the pre-processing code PRE_TEMP<0:2> from the value of the second sampling code TEMP2<0:2> to generate a second subtraction result DELT_TEMP2<0:2> and a second borrow signal BO_TEMP2. When the value of the second sampling code TEMP2<0:2> is greater than the value of the pre-processing code PRE_TEMP<0:2>, the second subtraction result DELT_TEMP2<0:2> has a value, not “000”, and the second borrow signal BO_TEMP2 is deactivated. In addition, when the value of the second sampling code TEMP2<0:2> is greater than the value of the pre-processing code PRE_TEMP<0:2>, the second borrow signal BO_TEMP2 is activated to “1”.

The comparison circuit 330 may compare the value of the first sampling code TEMP1<0:2> with the value of the second sampling code TEMP2<0:2> to generate an equality signal EQUAL. When the values of the two codes TEMP1<0:2> and TEMP2<0:2> are equal to each other, the equality signal EQUAL may be activated to “1”.

The logic operation unit 340 may perform a logic operation on the first subtraction result DELT_TEMP1<0:2>, the first borrow signal BO_TEMP1, the second subtraction result DELT_TEMP2<0:2> and the second borrow signal BO_TEMP2 to generate an increase signal INC and a decrease signal DEC.

The logic operation unit 340 may include NOR gates 341 and 348, inverters 342, 343, 345, 347, 349, 350, 352 and 354, and NAND gates 344, 346, 351 and 353. When the first subtraction result DELT_TEMP1<0:2> is not “000” and the first borrow signal BO_TEMP1 is deactivated to “0”, that is, when the value of the first sampling code TEMP1<0:2> is greater than the value of the pre-processing code PRE_TEMP<0:2>, a first increase signal INC_1 is activated to “1”. When the second subtraction result DELT_TEMP2<0:2> is not “000” and the second borrow signal BO_TEMP2 is deactivated to “0”, that is, when the value of the second sampling code TEMP2<0:2> is greater than the value of the pre-processing code PRE_TEMP<0:2>, a second increase signal INC_2 is activated to “1”. In addition, when both the first increase signal INC_1 and the second increase signal INC_2 are activated, the increase signal INC is activated to “1”.

When both the first borrow signal BO_TEMP1 and the second borrow signal BO_TEMP2 are activated to “1”, that is, when the value of the first sampling code TEMP1<0:2> is less than the value of the pre-processing code PRE_TEMP<0:2> and the value of the second sampling code TEMP2<0:2> is less than the value of the pre-processing code PRE_TEMP<0:2>, the decrease signal DEC is activated.

When the decrease signal DEC is activated, the operation circuit 370 may output the value obtained by subtracting the predetermined first value (as exemplified by “1”) from the value of the pre-processing code PRE_TEMP<0:2>, and when the increase signal INC is activated, the operation circuit 370 may output the value obtained by adding the predetermined second value (illustrated by “1”) to the value of the pre-processing code PRE_TEMP<0:2>.

The operation circuit 370 may include a selection circuit 371 and an addition circuit 372. The selection circuit 371 may select and output “000” when both the increase signal INC and the decrease signal DEC are deactivated, select and output “001” when the increase signal INC is activated, and select and output “111” when the decrease signal DEC is activated. The addition circuit 372 may add the value of the pre-processing code PRE_TEMP<0:2> and an output value of the selection circuit 371 to output a result value. Consequently, the output value of the addition circuit 372 may be outputted as a value equal to the value of the pre-processing code PRE_TEMP<0:2>, a value obtained by adding “1” to the value of the pre-processing code PRE_TEMP<0:2>, or a value obtained by subtracting “1” from the value of the pre-processing code PRE_TEMP<0:2>. For reference, a value obtained by adding “111” to a value of a code may be equal to a value obtained by subtracting “1” from the value of the code.

The selection circuit 380 may select the first sampling code TEMP1<0:2> and output the selected code as the processing code TEMP_VALID<0:2> when the equality signal EQUAL is activated to “1”, and select the output value of the operation circuit 370 and output the selected value as the processing code TEMP_VALID<0:2> when the equality signal EQUAL is deactivated to “0”.

The processing circuit 230 having the configuration described with reference to FIG. 3 may operate in the same manner as the cases (1), (2-1), (2-2) and (2-3) described earlier.

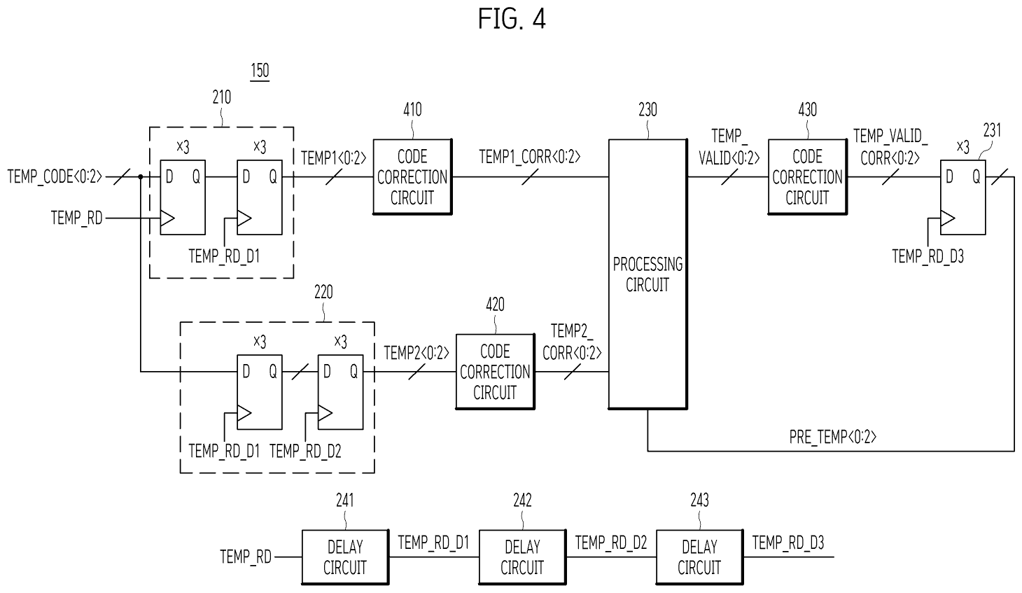

FIG. 4 is a block diagram illustrating another embodiment of the information code processor 150 illustrated in FIG. 1.

The information code processor 150 illustrated in FIG. 4 further may include code correction circuits 410, 420 and 430 compared to the information code processor 150 illustrated in FIG. 2.

When the value of the first sampling code TEMP1<0:2> deviates from a specified standard, the code correction circuit 410 may correct the value of the first sampling code TEMP1<0:2> to a value within the specified standard to output the corrected value. When the value of the second sampling code TEMP2<0:2> deviates from the specified standard, the code correction circuit 420 may correct the value of the second sampling code TEMP2<0:2> to a value within the specified standard to outputs the corrected value. Similarly, when the value of the processing code TEMP_VALID<0:2> deviates from the specified standard, the code correction circuit 430 may correct the value of the processing code TEMP_VALID<0:2> to a value within the specified standard to output the corrected value. Output TEMP_VALID_CORR<0:2> of the code correction circuit 430 may be the final output of the information code processor 150.

Table 1 represents an example of the specified standard for the information code TEMP_CODE<0:2>.

TABLE 1

| TEMP_CODE<0:2> | TEMPERATURE |
|---|---|
| 000 | undefined |
| 001 | below 80° C. |
| 010 | 80° C.-85° C. |
| 011 | 85° C.-90° C. |
| 100 | 90° C.-95° C. |
| 101 | over 95° C. |
| 110 | undefined |
| 111 | undefined |

When the value of the information code TEMP_CODE<0:2> is 001 to 101, Table 1 indicates information about the temperature. However, when the value of the information code TEMP_CODE<0:2> is 000, 110 or 111, the temperature is not defined. When the value of the information code TEMP_CODE<0:2> is 000, 110 or 111, it may be seen that the temperature has a value other than the specified specification, that is, an error.

When an inputted code value deviates from the specified specification, the code correction circuits 410, 420 and 430 may correct the inputted code value to a code value that meets the closest standard. Because it is important that a value of the final output code TEMP_VALID_CORR<0:2> of the information code processor 150 meets the standard, the code correction circuit 430 may be the most important among the code correction circuits 410, 420 and 430. That is, the code correction circuits 410 and 420 may be omitted, and only the code correction circuit 430 may be provided.

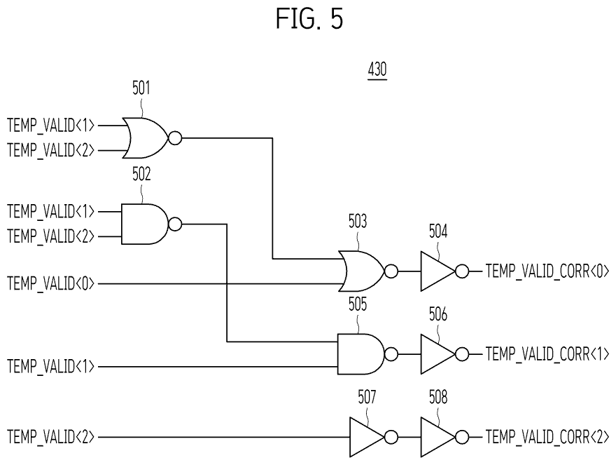

FIG. 5 is a block diagram illustrating an embodiment of the code correction circuit 430 illustrated in FIG. 4. Other code correction circuits 410 and 420 may have the same configuration as the code correction circuit 430 illustrated in FIG. 5.

Referring to FIG. 5, the code correction circuit 430 may include NOR gates 501 and 503, NAND gates 502 and 505, and inverters 504, 506, 507 and 508.

When the value of the processing code TEMP_VALID<1:2> is “00”, the value of the output code TEMP_VALID_CORR<0> may be fixed to “1” regardless of the value of the processing code TEMP_VALID<0>. Therefore, when the value of the processing code TEMP_VALID<0:2> is “000”, the value of the output code TEMP_VALID_CORR<0:2> may be “001”. That is, the code value of “000”, which does not meet the standard, may be corrected to “001”.

When the value of the processing code TEMP_VALID<1:2> is “11”, the value of the output code TEMP_VALID_CORR<1> may be fixed to “0” regardless of the value of the processing code TEMP_VALID<1>. Therefore, when the value of the processing code TEMP_VALID<0:2> is “110”, the value of the output code TEMP_VALID_CORR<0:2> may be “100”. In addition, when the value of the processing code TEMP_VALID<0:2> is “111”, the value of the output code TEMP_VALID_CORR<0:2> may be “101”. That is, the code value of “110”, which does not meet the standard, may be corrected to “100”, and the code value of “111”, which does not meet the standard, may be corrected to “101”.

Although according to embodiments described above, it is described that the information code processor 150 processes an information code including temperature information, the information code processor 150 may also be used to process an information code including other information than the temperature information.

Although the technical spirit of the present disclosure has been described above according to embodiments, this is only for describing the embodiments according to the concept of the present disclosure, and the present disclosure is not limited to the above embodiments. Various embodiments may be applied by those skilled in the art, to which the present disclosure pertains, within the scope of the technical spirit of the present disclosure. Furthermore, the embodiments may be combined to form additional embodiments.

What is claimed is:

1. An information code processor comprising:
a first sampling circuit configured to sample an information code at a first time point to generate a first sampling code;
a second sampling circuit configured to sample the information code at a second time point subsequent to the first time point to generate a second sampling code; and
a processing circuit configured to generate a processing code based on the first sampling code, the second sampling code and a pre-processing code generated previously.

2. The information code processor of claim 1, wherein the processing circuit is configured to generate the first sampling code as the processing code when a value of the first sampling code is equal to a value of the second sampling code.

3. The information code processor of claim 2, wherein the processing circuit is configured to generate the processing code having a value obtained by subtracting a predetermined first value from a value of the pre-processing code when the value of the first sampling code is different from the value of the second sampling code, and both values of the first and second sampling codes are less than the value of the pre-processing code.

4. The information code processor of claim 3, wherein the processing circuit is configured to generate the processing code having a value obtained by adding a predetermined second value to the value of the pre-processing code when the value of the first sampling code is different from the value of the second sampling code, and both values of the first and second sampling codes are greater than the value of the pre-processing code.

5. The information code processor of claim 4, wherein the processing circuit is configured to generate the processing code having a same value as the value of the pre-processing code when the value of the first sampling code is different from the value of the second sampling code, and both values of the first and second sampling codes are not less than the value of the pre-processing code, or both values of the first and second sampling codes are not greater than the value of the pre-processing code.

6. The information code processor of claim 1, further comprising a first code correction circuit configured to correct a value of the processing code to a value within a specified standard when the value of the processing code deviates from the specified standard.

7. The information code processor of claim 6, further comprising:
a second code correction circuit configured to correct, when a value of the first sampling code deviates from the specified standard, the value of the first sampling code to the value within the specified standard, and transmit the corrected value to the processing circuit; and
a third code correction circuit configured to correct, when a value of the second sampling code deviates from the specified standard, the value of the second sampling code to the value within the specified standard, and transmit the corrected value to the processing circuit.

8. The information code processor of claim 1, wherein the processing circuit includes:
a first subtraction circuit configured to subtract a value of the pre-processing code from a value of the first sampling code to generate a first subtraction result and a first borrow signal;
a second subtraction circuit configured to subtract the value of the pre-processing code from a value of the second sampling code to generate a second subtraction result and a second borrow signal;
a comparison circuit configured to compare the value of the first sampling code with the value of the second sampling code to generate an equality signal;
a logic operation unit configured to perform a logic operation on the first subtraction result, the first borrow signal, the second subtraction result and the second borrow signal to generate an increase signal and a decrease signal;
an operation circuit configured to output a value obtained by subtracting a predetermined first value from the value of the pre-processing code when the decrease signal is activated, output a value obtained by adding a predetermined second value to the value of the pre-processing code when the increase signal is activated, and output the value of the pre-processing code when the increase signal and the decrease signal are deactivated; and
a selection circuit configured to select, when the equality signal is deactivated, an output code of the operation circuit to output the selected code as the processing code, and select, when the equality signal is activated, the first sampling code to output the selected code as the processing code.

9. The information code processor of claim 8, wherein the logic operation unit is configured to activate the decrease signal when the first borrow signal and the second borrow signal are activated, and activate the increase signal when the first borrow signal and the second borrow signal are deactivated and the first subtraction result and the second subtraction result are not “0”.

10. A memory comprising:
a temperature sensing circuit configured to generate an information code indicating a temperature;
a command decoder configured to decode a command and an address to generate a temperature read signal;
a first sampling circuit configured to sample the information code at a first time point in response to the temperature read signal to generate a first sampling code;
a second sampling circuit configured to sample the information code at a second time point subsequent to the first time point in response to the temperature read signal to generate a second sampling code;
a processing circuit configured to generate a processing code based on the first sampling code, the second sampling code and a pre-processing code generated previously; and
a transmitting circuit configured to externally transmit the processing code.

11. The memory of claim 10, wherein the processing circuit is configured to generate the first sampling code as the processing code when a value of the first sampling code is equal to a value of the second sampling code.

12. The memory of claim 11, wherein the processing circuit is configured to generate the processing code having a value obtained by subtracting a predetermined first value from a value of the pre-processing code when the value of the first sampling code is different from the value of the second sampling code, and both values of the first and second sampling codes are less than the value of the pre-processing code.

13. The memory of claim 12, wherein the processing circuit is configured to generate the processing code having a value obtained by adding a predetermined second value to the value of the pre-processing code when the value of the first sampling code is different from the value of the second sampling code, and both values of the first and second sampling codes are greater than the value of the pre-processing code.

14. The memory of claim 13, wherein the processing circuit generates the processing code having a same value as the value of the pre-processing code when the value of the first sampling code is different from the value of the second sampling code, and both values of the first and second sampling codes are not less than the value of the pre-processing code, or both values of the first and second sampling codes are not greater than the value of the pre-processing code.

15. The memory of claim 10, further comprising a first code correction circuit configured to correct a value of the processing code to a value within a specified standard when the value of the processing code deviates from the specified standard.

16. The memory of claim 15, further comprising:
a second code correction circuit configured to correct, when a value of the first sampling code deviates from the specified standard, the value of the first sampling code to the value within the specified standard, and transmit the corrected value to the processing circuit; and
a third code correction circuit configured to correct, when a value of the second sampling code deviates from the specified standard, the value of the second sampling code to the value within the specified standard, and transmit the corrected value to the processing circuit.

17. A method of operating a memory, the method comprising:
generating an information code indicating a temperature;
decoding a command and an address to generate a temperature read signal;
sampling the information code at a first time point in response to the temperature read signal to generate a first sampling code;
sampling the information code at a second time point subsequent to the first time point in response to the temperature read signal to generate a second sampling code; and
generating a processing code based on the first sampling code, the second sampling code and a pre-processing code generated previously to externally transmit the processing code.

18. The method of claim 17, further comprising correcting a value of the processing code to a value within a specified standard when the value of the processing code deviates from the specified standard.

19. The method of claim 18, further comprising:
correcting, when a value of the first sampling code deviates from the specified standard, the value of the first sampling code to the value within the specified standard, and transmitting the corrected value to the processing circuit; and
correcting, when a value of the second sampling code deviates from the specified standard, the value of the second sampling code to the value within the specified standard, and transmitting the corrected value to the processing circuit.
